(19) United States
(12) Patent Application Publication
(10) Pub. No.: US 2025/0060298 A1
(43) Pub. Date: Feb. 20, 2025

(54) IN-SITU PARTICLE DETECTION

(71) Applicant: Applied Materials, Inc., Santa Clara, CA (US)

(72) Inventors: Wei Weng, Sunnyvale, CA (US); Chang Ke, Sunnyvale, CA (US); Changgong Wang, San Jose, CA (US)

(21) Appl. No.: 18/801,057

(22) Filed: Aug. 12, 2024

Related U.S. Application Data
(60) Provisional application No. 63/533,323, filed on Aug. 17, 2023.

(51) Int. Cl. G01N 15/06; H01J 37/32

(52) U.S. Cl. CPC G01N 15/0656; G01N 15/0606; H01J 37/32091; H01J 37/3211; H01J 37/32541; H01J 37/32568; H01J 37/32981

(57) ABSTRACT

A processing system includes a processing chamber defining a processing region. A foreline is coupled with the processing chamber and defines a fluid conduit. A plasma trap is provided within an interior of the foreline to charge and trap at least some particles in the fluid conduit. The system further includes a particle detector to collect at least some of the charged particles and measure an electric charge produced by the particles.

### CLAIM OF PRIORITY

The present application claims the benefit under 35 U.S.C. § 119 (e) of U.S. Provisional Patent Application No. 63/533,323 filed Aug. 17, 2023, which is incorporated by reference herein.

### TECHNICAL FIELD

Embodiments of the present disclosure relate to a method for detecting particles in a processing system, and a processing chamber with in-situ particle detection.

### BACKGROUND

In processing systems, particles are detected using various methods and tools to ensure the quality and reliability of the devices being manufactured. Particle detection is performed in processing to minimize defects and ensure the performance and yield of devices. Some methods for in-situ particle detection include light scattering and charge measurement. However, in order for light scattering to work, the particle should be of a minimum size. Therefore, particles less than about 100 nm generally go undetected. Additionally, the detection sensitivity decreases as particle velocity increases. The charge measurement method is able to detect particles of smaller size. However, this method requires a high particle concentration to generate signals, which makes it generally unsuitable for processing systems.

### SUMMARY

Some embodiments of the present invention cover a processing system. The system includes a processing chamber defining a processing region. A foreline is coupled with the processing chamber and defines a fluid conduit. A plasma trap is provided within an interior of the foreline to charge and trap at least some particles in the fluid conduit. The system further includes a particle detector to collect at least some of the charged particles and measure an electric current produced by the particles.

In some embodiments, the present invention covers a method for in-situ particle detection. The method includes electrostatically charging, through a plasma source, particles in a medium, to form charged particles. The method further includes trapping the charged particles in the plasma for a time period for accumulation and then remove the trapping force to release the charged particles to flow into a conduit. The method further includes collecting at least some of the charged particles released in the conduit onto a conductive medium, and measuring an electric current produced by the charged particles collected on the conductive medium.

In some embodiments, the present invention covers a method for in-situ particle detection. The method includes providing a plasma trap in a conduit of a processing chamber. The method further includes charging particles in the plasma trap for a predetermined period of time and releasing the charged particles after the predetermined period of time expires. The method further includes collecting at least some of the charged particles on a metal plate, and measuring an electric current produced by the charged particles collected on the metal plate.

### BRIEF DESCRIPTION OF THE DRAWINGS

The present disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIG. 1 depicts a sectional view of one embodiment of a processing chamber.

FIG. 2A depicts a sectional view of a processing system with in-situ particle detection, according to an embodiment.

FIG. 2B depicts a sectional view of a foreline in a processing system with in-situ particle detection, according to an embodiment.

FIG. 3A depicts a sectional view of a foreline in a processing system with a plasma trap, according to an embodiment.

FIG. 3B depicts a sectional view of a foreline in a processing system with in-situ particle detection, according to an embodiment.

FIG. 4 depicts a sectional view of a processing system with in-situ particle detection, according to an embodiment.

FIG. 5 illustrates a method for in-situ particle detection in a processing system, according to an embodiment.

FIG. 6 illustrates a method for in-situ particle detection in a processing system, according to an embodiment.

### DETAILED DESCRIPTION OF EMBODIMENTS

Embodiments are described herein with reference to a processing system such as a semiconductor processing system, a processing system for manufacturing displays, a photovoltaic processing system, and so on with in-situ particle detection. Embodiments provide a plasma trap that traps charged particles accumulated over a time period, and a particle detector that detects the accumulated particles by detecting the charge carried by the particles. In some embodiments, the plasma trap and/or particle detector are disposed in an exhaust line or foreline of a process chamber. In some embodiments, the plasma trap and/or particle detector are disposed within a process chamber. In some embodiments, the plasma trap is disposed within the process chamber, and the particle detector is disposed in the exhaust line or foreline. In some embodiments, the particle detector is a charge-measurement particle detector. The concentration of particles in a process chamber during and/or after processing may be too low for detection by a charge-measurement particle detector. However, in some embodiments a plasma trap or other types of trap (e.g., such as an electrostatic trap) may trap particles for a period of time, after which the trapped particles may be released. The concentration of particles may build up over time in the plasma trap, resulting in a concentration that is detectable by the charge-measurement particle detector. Accordingly, embodiments enable use of a charge-measurement particle detector to detect low concentrations of particles. Such detection can be performed in real-time or near real-time during and/or between process runs, and results of the particle detection may be used to automatically trigger recovery, such as a cleaning or other maintenance.

In embodiments, a system has a processing chamber that defines a processing region (e.g., for design, manufacture, or testing of a semiconductor device). The processing chamber may be used for chemical vapor deposition (CVD), physical vapor deposition (PVD), etching, or other processes typically involved in a manufacturing process. A foreline having a fluid conduit is coupled with the processing chamber. A plasma trap is provided within an interior of the foreline so that at least some particles in the fluid conduit can be charged and trapped within the plasma trap. The particles are then released, periodically, onto a metal plate which is connected to a charge detector (e.g., electrometer) to measure the charge or current produced by the charged particles on the metal plate. The metal plate may include one or more of nickel, copper, gold, silver, platinum, stainless steel, or other conductive materials. An outlet pump coupled to a distal end of the fluid conduit may be used to expunge the fluid out of the foreline, from time to time. In some embodiments, the plasma may be generated in a capacitively coupled mode (CCP). The plasma trap may have a pair of ring electrodes separated by a predetermined distance. The ring electrodes are disposed within an interior of the foreline using insulators that separate the ring electrodes from the interior walls of the foreline. A radio frequency (RF) source is coupled to the ring electrodes. The radio frequency source applies an RF signal to the ring electrodes to generate a plasma in a region between the electrodes. The plasma then charges at least some of the particles in the fluid conduit. The charged particles then get trapped in the plasma between the two electrodes. In some embodiments, the plasma may be generated in an inductively coupled mode (ICP). A metal coil may be wound around an outside surface of the foreline made from electrically insulating materials, and an RF source may be coupled to the metal coil for generating plasma within the foreline. In some embodiments, a grounded metal mesh may be installed in between the trapping plasma and metal plate to block ions and electrons from passing onto the metal plate.

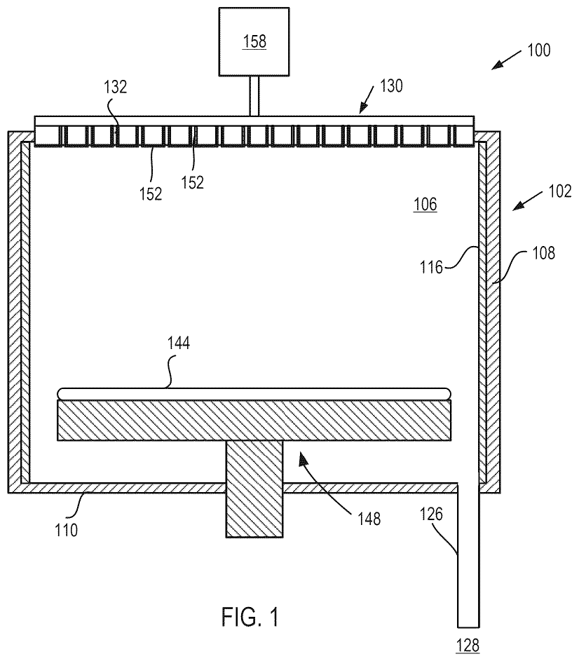

FIG. 1 is a sectional view of a processing chamber 100 having one or more chamber components in accordance with embodiments of the present invention. The processing chamber 100 may be used for processes in which a corrosive plasma environment having plasma processing conditions is provided. For example, the processing chamber 100 may be a chamber for a plasma etcher or plasma etch reactor, a plasma cleaner, and so forth. Additionally, or alternatively, the processing chamber 100 may be used to perform processes that do not use plasma. Examples of chamber components may include chamber components with complex shapes and holes having large aspect ratios. Some example chamber components include a substrate support assembly 148, an electrostatic chuck (ESC), a ring (e.g., a process kit ring or a single ring), a chamber wall, a base, a gas distribution plate, a showerhead 130, gas lines, a nozzle, a lid, a liner, a liner kit, a shield, a plasma screen, a flow equalizer, a cooling base, a chamber viewport, a chamber lid, and so on. A protective coating may be applied to one or more of these components. The protective coating may be an oxide based ceramic such as SiO₂ (quartz), Al₂O₃, Y₂O₃, Y₃Al₅O₁₂, Y₄Al₂O₉, Y₂O₃—ZrO₂ and so on.

In one embodiment, the processing chamber 100 includes a chamber body 102 and a showerhead 130 that enclose an interior volume 106. The showerhead 130 may include a showerhead base and a showerhead gas distribution plate. Alternatively, the showerhead 130 may be replaced by a lid and a nozzle in some embodiments. The chamber body 102 may be fabricated from aluminum, stainless steel, or other suitable material. The chamber body 102 generally includes sidewalls 108 and a bottom 110. Any of the showerhead 130 (or lid and/or nozzle), sidewalls 108 and/or bottom 110 may include a multi-component coating.

An outer liner 116 may be disposed adjacent the sidewalls 108 to protect the chamber body 102. The outer liner 116 may be fabricated and/or coated with a multi-component coating. In one embodiment, the outer liner 116 is fabricated from aluminum oxide.

A foreline 126 may be defined in the chamber body 102 and/or attached to the chamber body 102, and may couple the interior volume 106 to an outlet pump system 128. The outlet pump system 128 may include one or more pumps and/or throttle valves utilized to evacuate and regulate the pressure of the interior volume 106 of the processing chamber 100.

The showerhead 130 may be supported on the sidewall 108 and/or top of the chamber body 102. The showerhead 130 (or lid) may be opened to allow access to the interior volume 106 of the processing chamber 100 in some embodiments, and may provide a seal for the processing chamber 100 while closed. A fluid/gas panel 158 may be coupled to the processing chamber 100 to provide process and/or cleaning fluids to the interior volume 106 through the showerhead 130 or lid and nozzle. The showerhead 130 may include a gas distribution plate (GDP) having multiple gas delivery holes 132 throughout the GDP. The showerhead 130 may include the GDP bonded to an aluminum showerhead base or an anodized aluminum showerhead base. The GDP 133 may be made from Si or SiC, or may be a ceramic such as Y₂O₃, Al₂O₃, YAG, and so forth. Showerhead 130 and delivery holes 132 may be coated with a multi-component coating. As illustrated, the showerhead 130 has a multi-component coating 152 both on a surface of the showerhead 130 (e.g., e.g., on a surface of a showerhead base and/or a surface of a GDP) and on walls of gas conduits (also referred to as holes) 132 in the showerhead (e.g., in the showerhead base and/or GDP), in accordance with one embodiment. However, it should be understood that any of the other chamber components, such as gas lines, electrostatic chucks, nozzles and others, may also be coated with a multi-component coating.

For processing chambers used for conductor etch (etching of conductive materials), a lid may be used rather than a showerhead. The lid may include a center nozzle that fits into a center hole of the lid. The lid may be a ceramic such as Al₂O₃, Y₂O₃, YAG, or a ceramic compound comprising Y₄Al₂O₉ and a solid-solution of Y₂O₃—ZrO₂. The nozzle may also be a ceramic, such as Y₂O₃, YAG, or the ceramic compound comprising Y₄Al₂O₉ and a solid-solution of Y₂O₃—ZrO₂.

The lid, showerhead 130 (e.g., including showerhead base, GDP and/or gas delivery conduits/holes) and/or nozzle may all be coated with a multi-component coating according to an embodiment.

Examples of processing gases that may be used to process substrates in the processing chamber 100 include halogen-containing gases, such as C₂F₆, SF₆, SiCl₄, HBr, NF₃, CF₄, CHF₃, CH₂F₃, F, NF₃, Cl₂, CCl₄, BCl₃ and SiF₄, among others, and other gases such as O₂, or N₂O. Examples of carrier gases include N₂, He, Ar, and other gases inert to process gases (e.g., non-reactive gases). The substrate support assembly 148 is disposed in the interior volume 106 of the processing chamber 100 below the showerhead 130 or lid. The substrate support assembly 148 holds the substrate 144 during processing and may include an electrostatic chuck bonded to a cooling plate. An inner liner may be coated on the periphery of the substrate support assembly 148. The inner liner may be a halogen-containing gas resist material such as those discussed with reference to the outer liner 116. In one embodiment, the inner liner 118 may be fabricated from the same materials of the outer liner 116.

Over time, an interior of the processing chamber 100 may experience a buildup of particles, a buildup of a residual coating caused by process gases, a degradation of surface conditions, and so on. During subsequent processing, flowing of gases in the process chamber, movement of components within the process chamber, and so on, particles from the interior surfaces of the processing chamber may become dislodged and become airborne. Such particles may ultimately deposit on substrates. In embodiments, a particle detection system is included in or attached to the processing chamber to detect the amount of particles. The measurements provided by the particle detection system may then be used to determine when to perform maintenance such as a cleaning process for the processing chamber.

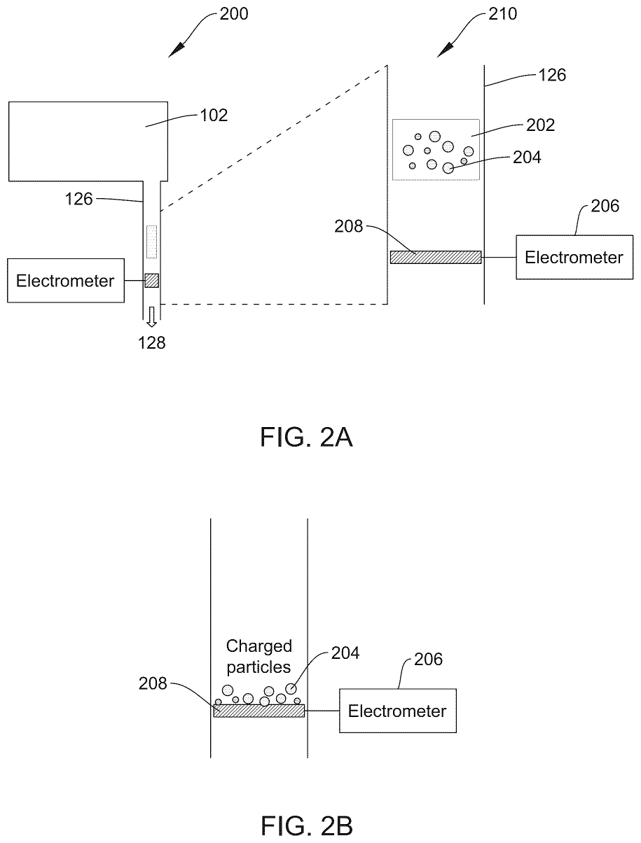

FIG. 2A depicts a sectional view of one embodiment of a processing system 200 with in-situ particle detection, according to one embodiment. The system 200 has a processing chamber 102, as described in further detail in FIG. 1. Processing chamber 102 defines a processing region (e.g., for design, manufacture, or testing of a device). The processing chamber 102 may be used for various microchip manufacturing processes including chemical vapor deposition (CVD), physical vapor deposition (PVD), lithography, oxidation, etching, etc. The processing chamber can also be used for wafer passing through, for example, like a load lock. A foreline 126 having a fluid conduit is coupled with the processing chamber 102, as described in further detail in FIG. 1.

A plasma trap 210 is provided within an interior of the foreline 126 so that at least some particles 204 in the fluid conduit can be charged and trapped within the plasma trap 210. The plasma can be confined within the foreline using a magnetic field generated by magnets or electromagnets. Such confinement may prevent the plasma from contacting the walls of the device and/or may prevent the plasma from moving to a different region outside of the plasma trap. The charged particles get trapped inside a plasma due to the electrostatic force. The particles are negatively charged inside a plasma due to the higher electrical mobility of electrons compared to cations. Plasma has a higher electrical potential compared to its surroundings, and therefore the particles at the plasma sheath are subject to an electrostatic force pointing towards the center of the plasma. Thus the particles get trapped in the plasma when the electrostatic force is in balance with other forces such as ion drag force.

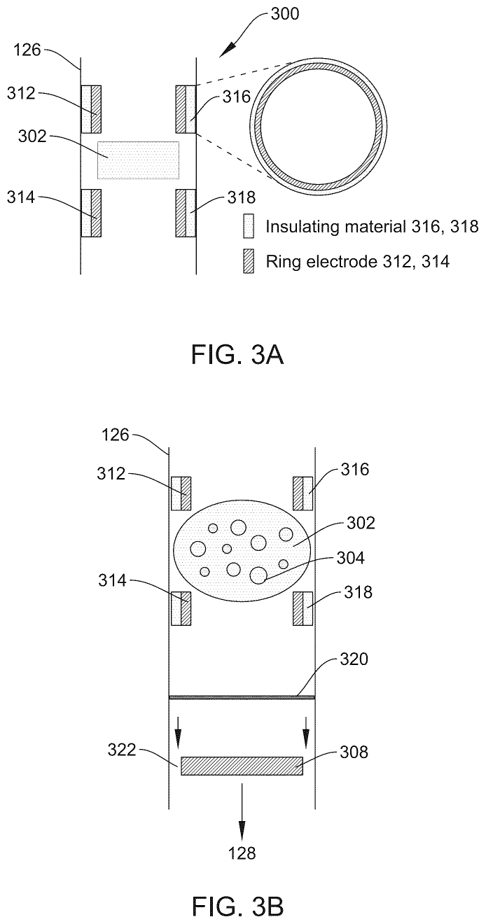

The plasma 202 in the foreline 126 can be generated in a capacitive coupling (CCP) mode or an inductive coupling (ICP) mode. The CCP mode is described in further detail with respect to FIGS. 3A & 3B. In the ICP mode, a metal coil (not shown) may be wound around the outside surface of the foreline 126 and may be powered using a radio frequency (RF) source to generate the plasma 202. For the ICP mode, the foreline 126 may be made from an electrically isolating material, such as quartz, for example. The plasma trap may be activated for a time period, during which particles may become charged by the plasma and be trapped within the plasma trap. The plasma trap may be periodically deactivated to permit the trapped particles to leave the plasma trap and migrate to or be pumped to a particle detector in the foreline 126 downstream of the plasma trap.

After the particles 204 are charged and trapped in the plasma 202 for a predetermined period of time, the particles 204 may be released, periodically, onto a metal plate 208 (as shown in FIG. 2B) which may be connected to an electrometer 206 to measure the electric current produced by the charged particles 204 on the metal plate 208. The metal plate 208 may include one or more of nickel, copper, gold, silver, platinum, stainless steel, or other conductive materials. In some embodiments, the predetermined period of time during which the particles 204 are charged and trapped in the plasma trap can be based at least in part on a diameter of a smallest particle in the particles, a concentration of the particles in the fluid, a flow rate of the fluid, the least current measurable by the electrometer, or a combination thereof. In some embodiments, the time period for trapping the particles is determined based on a design of experiments and/or empirical knowledge. An outlet pump system 128 may be coupled to a distal end of the fluid conduit and may be used to expunge the fluid out of the foreline 126, from time to time.

The current produced by the particles in the fluid can be given by the formula:

$$I = Q / t$$

Where “I” is the electric current generated by the charged particles, “Q” is the charge on the particles collected by the metal plate during time “t.” Therefore, if the current signal is to be amplified for easy detection, then either the charge should be increased, or the time should be reduced. In some embodiments disclosed herein, the charge may be increased by using plasma instead of other charging sources such as corona discharge. In some embodiments, the time of charge collection is reduced by releasing trapped particles all at once or over a short time interval. Plasma has a higher charging efficiency compared to conventional corona discharge. For example, if the particle diameter is around 10 nm, then elementary charge per particle for corona discharge is less than 1. However, for the same particle diameter, the elementary charge per particle for plasma is about 10¹. Similarly, if the particle diameter is around 100 nm, then elementary charge per particle for corona discharge is about 1. However, for the same particle diameter, the elementary charge per particle for plasma is about 10².

The pressure range for the fluid (e.g., gasses) in the conduit can be in the range of 10⁻¹ to 10⁻² torr, although other ranges are also within the scope of this embodiment. The frequency range of the RF source can be in the range of 10-40 MHz, for example, although other ranges are also within the scope of this embodiment. The power used to power the RF source and generate plasma can be in the range of 10²-10³ Watts, although other ranges are also within the scope of this embodiment. In some embodiments, the diameter of the particles can be an average of about 5-10 nm. The concentration of the particles can be around 10⁻³ particles per cubic centimeter in some embodiments. The flow rate of the fluid can be around 5000 standard cubic centimeters per minute (sccm) in some embodiments. The detection limit of the electrometer can be around 0.1 fA or higher in embodiments. The fluid within the processing system may include any gas such as nitrogen or any inert gas including but not limited to argon, neon, helium, krypton, xenon, and radon.

FIG. 3A depicts a plasma trap 300 in a processing system with in-situ particle detection, according to an embodiment. In this embodiment, the plasma 302 in the foreline 126 can be generated using a capacitive coupling (CCP) mode. In the CCP mode, the plasma trap 300 may have a pair of ring electrodes 312, 314 separated by a predetermined distance. The ring electrodes 312, 314 are disposed within an interior of the foreline 126 using insulators 316, 318 that separate the ring electrodes 312, 314 from the interior walls of the foreline 126, respectively. A radio frequency (RF) source (not shown) may be coupled to the ring electrodes 312, 314. As illustrated in FIG. 3B, the RF source applies an RF signal to the ring electrodes 312, 314 to generate a plasma 302 in a region between the electrodes 312, 314. The plasma 302 then charges at least some of the particles in the fluid conduit, between the two electrodes 312, 314, and those charged particles become trapped in the plasma trap 300. In some embodiments, the plasma 302 in the foreline 126 can be generated in a inductively coupling mode (ICP) where a metal coil may be wound around an outside surface of the foreline 126, and an RF source may be coupled to the metal coil for generating plasma within the foreline. However, in such an arrangement, the foreline may be made from an electrically isolating material, such as quartz, for example.

In some embodiments, a grounded metal mesh 320 can be installed between the plasma 302 and the metal plate 308 to serve as an ion blocker. The metal plate 308 may include one or more of nickel, copper, gold, silver, platinum, stainless steel, or other conductive materials. The ion blocker may block ions and electrons in the plasma 302 from reaching the metal plate 308, thereby avoiding any noise that may be generated as a result of ions and electrons present in the plasma 302. The pore size of the metal mesh 320 can be about 500-1000 microns and the material used for the metal mesh 320 may include any conductive metal including but not limited to copper and steel. In some embodiments, the metal mesh 320 may cover the entire circular area of the fluid conduit. In some embodiments, the metal mesh 320 may only cover a portion of the circular area of the fluid conduit. In some embodiments, the metal mesh may be grounded.

Although referred to as a metal plate 308, the particle collector can be made of any conductive material with low resistivity, including but not limited to copper. The particle collector may be a metal plate with no pores, or a metal plate with pores. If a metal plate with no pores is used, the area of the metal plate may cover only a portion of the area of the fluid conduit in order to allow the fluid/gas to flow through gaps 322 between the plasma trap and the outlet pump system 128. In some embodiments, the metal plate 308 may cover about 50-80% of the area of the fluid conduit. If a porous metal plate is used, then the porous metal plate may cover the entire cross-sectional area of the fluid conduit. The metal plate 308 can be a flat plate or it can be shaped to take any desired form, such as a cup shape. The porosity and thickness of the porous metal plate 308 may depend on the efficiency with which the particles may be collected and the fluid/gas conductance.

The pressure range for the fluid in the conduit can be in the range of 10⁻¹ to 10⁻² torr, although other ranges are also within the scope of this embodiment. The frequency of the RF source can be in the range of 10-40 MHz, for example, although other ranges are also within the scope of this embodiment. The power used to power the RF source and generate plasma can be in the range of 10²-10³ Watts, although other ranges are also within the scope of this embodiment. In some embodiments, the diameter of the particles can be an average of about 5-10 nm. The concentration of the particles can be around 10⁻³ particles per cubic centimeter. The flow rate of the fluid can be around 5000 standard cubic centimeters per minute (sccm). The detection limit of the electrometer can be around 0.1 fA or higher. The fluid within the processing system may include any gas such as nitrogen or any inert gas including but not limited to argon, neon, helium, krypton, xenon, and radon.

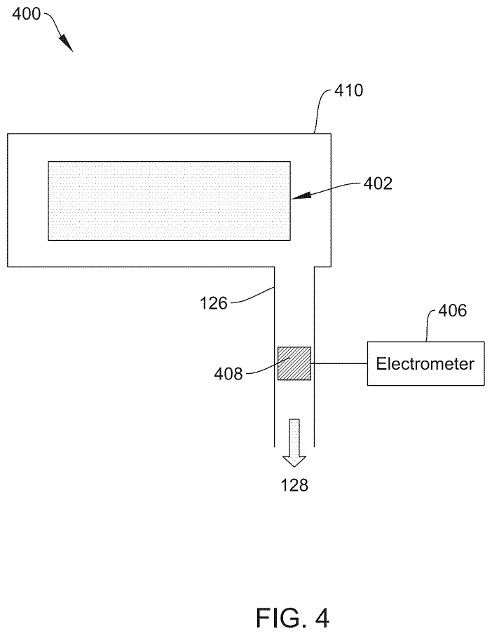

FIG. 4 depicts a processing system 400 with in-situ particle detection in which plasma already present in a processing chamber is used to charge and/or trap particles, according to an embodiment. One advantage of using such plasma trap system is that the foreline design can be much simpler as compared to a system in which plasma is generated in the foreline. The system 400 has a processing chamber 410 similar to processing chamber 102 described in FIG. 1. Processing chamber 410 defines a processing region (e.g., for design, manufacture, or testing of a device). The processing chamber 102 may be used for chemical vapor deposition (CVD), physical vapor deposition (PVD), etching, or other processes involved in a manufacturing process. A foreline 126 having a fluid conduit is coupled with the processing chamber 410, as described in further detail in FIG. 1. In this embodiment, the chamber 410 itself acts as a plasma trap so that at least some particles in the fluid in the chamber 410 are charged and trapped. The plasma 402 can be generated in the CCP mode by using a pair of parallel electrodes in the chamber, or in the ICP mode by using a metal coil (not shown) that may be wound around the outside surface of the chamber 410. A radio frequency (RF) source may be connected to the parallel electrodes or the metal coil to generate the plasma 402.

After the particles are charged and trapped in the plasma 402 for a predetermined period of time, the particles may be released, periodically, onto a metal plate 408 which may be connected to an electrometer 406 to measure the electric current produced by the charged particles on the metal plate 408. In some embodiments, the predetermined period of time during which the particles are trapped and charged in the chamber 410 can be based at least in part on a diameter of a smallest particle in the particles, a concentration of the particles in the fluid, a flow rate of the fluid, the least current measurable by the electrometer, or a combination thereof. An outlet pump system 128 may be coupled to a distal end of the fluid conduit and may be used to expunge the fluid out of the foreline 126, from time to time.

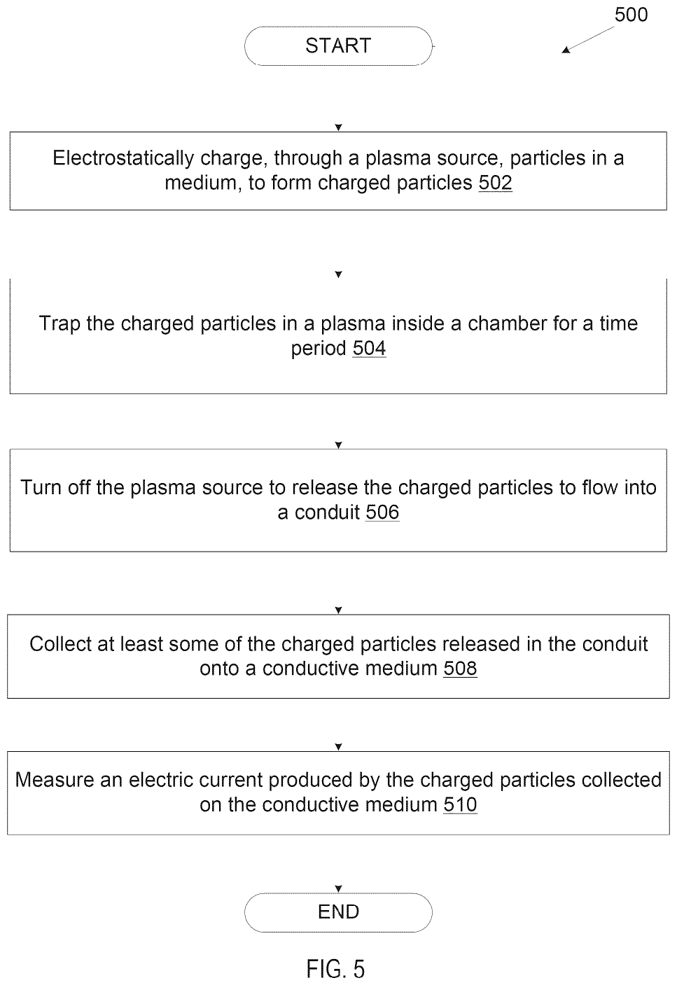

FIG. 5 illustrates a method 500 for in-situ particle detection in a processing system, according to an embodiment. Method 500 may be performed by a controller for a processing chamber, for a tool cluster, and so on. The controller (e.g., a tool and equipment controller, a tool cluster controller, etc.) may control various aspects of a cluster tool or processing chamber, e.g., such as gas pressure in the processing chambers, individual gas flows, spatial flow ratios, plasma power, temperature, radio frequency (RF) or electrical state of the processing chamber, and so on. The controller may receive signals from and send commands to any of the components of a tool cluster, such as the robot arms, process chambers, load locks, slit valve doors, and/or one or more sensors, and/or other processing components of the cluster tool. The controller may thus control the initiation and cessation of processing, may adjust a deposition rate and/or target layer thickness, may adjust process temperatures, may adjust a type or mix of deposition composition, may adjust an etch rate, may initiate automated prevention and/or recovery processes on the processing chamber, and the like. The controller may further receive sensor measurement data (e.g., particle count data) from various sensors and make decisions based on such measurement data.

In various embodiments, the controller may be and/or include a computing device such as a personal computer, a server computer, a programmable logic controller (PLC), a microcontroller, and so on. The controller may include (or be) one or more processing devices, which may be general-purpose processing devices such as a microprocessor, central processing unit, or the like. More particularly, the processing device may be a complex instruction set computing (CISC) microprocessor, reduced instruction set computing (RISC) microprocessor, very long instruction word (VLIW) microprocessor, or a processor implementing other instruction sets or processors implementing a combination of instruction sets. The processing device may also be one or more special-purpose processing devices such as an application specific integrated circuit (ASIC), a field programmable gate array (FPGA), a digital signal processor (DSP), network processor, or the like. The controller may include a data storage device (e.g., one or more disk drives and/or solid state drives), a main memory, a static memory, a network interface, and/or other components. The processing device of the controller may execute instructions to perform any one or more of the methodologies and/or embodiments described herein. The instructions may be stored on a computer readable storage medium, which may include the main memory, static memory, secondary storage and/or processing device (during execution of the instructions). In some embodiments, controller is a dedicated controller for a processing chamber.

At block 502, the method may involve electrostatically charging particles in a medium using a plasma. The method may further include flowing gas at a low flow rate (e.g., hundreds of sccm). The next operation involves igniting the plasma by turning on the RF source at a low power (e.g., less than the target or final power). The next operation involves increasing the gas flow rate (e.g., to thousand of sccm) and agitating the gas/fluid to levitate the particles adhered to any inside chamber parts.

At block 504, the method involves trapping the charged particles in the plasma inside a chamber for a time period. In this operation, the RF power is increased to a target value such that when the gas drag force and the electrostatic force exerted on the particles reaches a balance, the particles will be trapped in the plasma.

At block 506, the method involves turning off the plasma to release the charged particles to flow into a conduit. In this operation, after some time of trapping and accumulation, the RF source is turned off and the charged particles are released onto a conductive medium of a particle detector by means of an outlet pump, which can be activated to expunge the fluid in the chamber. At block 508, the method involves collecting at least some of the charged particles released in the conduit onto a conductive medium, such as a metal plate. At block 510, the method involves measuring an electric current produced by the charged particles collected on the conductive medium (e.g., metal plate).

In some embodiments, a diameter of the charged particles can be less than 100 nm, which are generally undetectable by other detection tools, or larger than 100 nm. In some embodiments, a particle concentration of the charged particles with a diameter of 10 nm can be less than 400 particles/cm³, which is generally unsuitable for other detection tools based on electrical charge measurements. Therefore, an advantage of the systems and methods disclosed herein is that they can be used for in-situ particle detection regardless of the particle size or particle concentration.

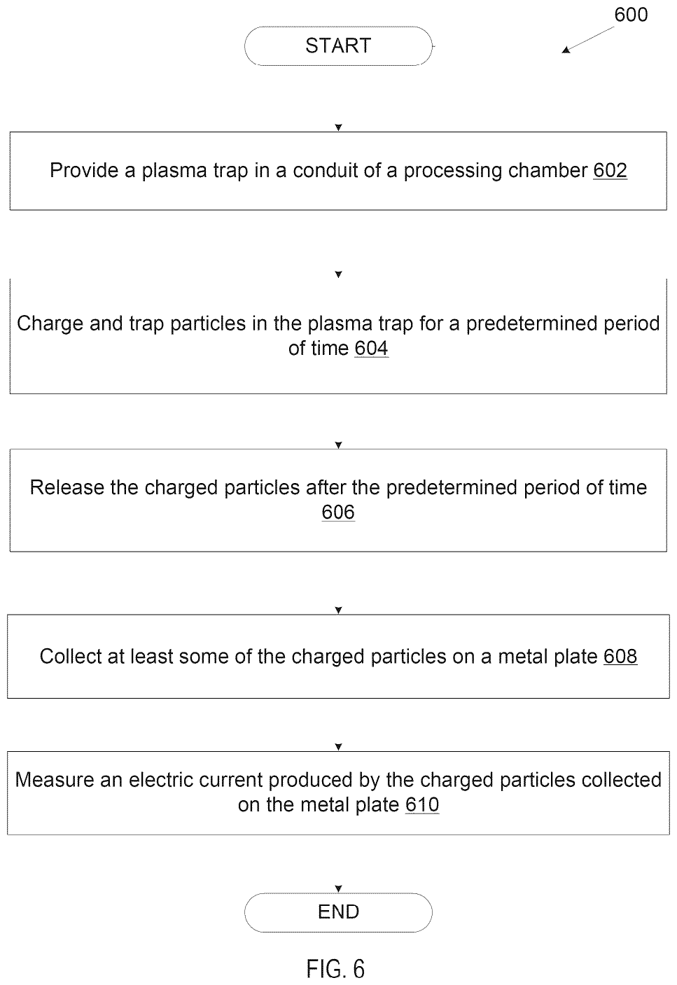

FIG. 6 illustrates another method 600 for in-situ particle detection in a processing system, according to an embodiment. At block 602, the method involves providing a plasma trap in a conduit of a processing chamber, such as the processing chamber 102 described in FIG. 1. The method involves first flowing gas at a low flow rate (e.g., hundreds of sccm). The method further involves igniting the plasma by turning on the RF source at a low power (e.g., less than the target or final power). The particles may be charged by inducing a plasma in embodiments, such as by applying an RF signal to one or more components of a plasma trap. The particles may also be charged by using negative corona discharge in the conduit upstream from the trapping plasma. The method further involves increasing the gas flow rate (e.g., to thousand of sccm) and agitating the gas/fluid to levitate the particles adhered to any inside chamber parts.

At block 604, the method involves charging particles in the plasma trap for a predetermined period of time. This may be performed by increasing the RF power to a target value such that when the gas drag force and the electrostatic force exerted on the particles reaches a balance, the particles will be trapped in the plasma.

At operation 606, the method involves releasing the charged particles after the predetermined period of time. After some time of trapping and accumulation, the RF source is turned off and the charged particles are released onto the metal plate by means of an outlet pump, which can be activated to expunge the fluid in the chamber. At block 608, the method involves collecting at least some of the charged particles on a conductive medium such as a metal plate. At operation 610, the method involves measuring an electric current produced by the charged particles collected on the conductive medium.

In some embodiments, a diameter of the charged particles can be less than 100 nm, which are generally undetectable by other detection tools, or larger than 100 nm. In some embodiments, a particle concentration of the charged particles with a diameter of 10 nm can be less than 400 particles/cm³, which is generally unsuitable for other detection tools based on electrical charge measurements. Therefore, an advantage of the systems and methods disclosed herein is that they can be used for in-situ particle detection regardless of the particle size or particle concentration.

In some embodiments, a grounded metal mesh can be installed between the plasma trap and the conductive medium to serve as an ion blocker. The ion blocker may block ions and electrons in the plasma from reaching the metal plate, thereby avoiding any noise that may be generated as a result of ions and electrons present in the plasma. The pore size of the metal mesh can be about 500-1000 microns and the material used for the metal mesh may include any conductive metal including but not limited to copper and steel. In some embodiments, the metal mesh may cover the entire circular area of the fluid conduit. In some embodiments, the metal mesh may only cover a portion of the circular area of the fluid conduit.

Although referred to as a “metal plate” in some embodiments, the particle collector can be made of any conductive material with low resistivity, including but not limited to copper. The particle collector may be a metal plate with no pores, or a metal plate with pores. If a metal plate with no pores is used, the area of the metal plate may cover only a portion of the area of the fluid conduit in order to allow the fluid/gas to flow from the plasma trap to the outlet pump. In some embodiments, the metal plate may cover about 50-80% of the area of the fluid conduit. If a porous metal plate is used, then the porous metal plate may cover the entire cross-sectional area of the fluid conduit. The metal plate can be a flat plate or it can be shaped to take any desired form, such as a cup shape. The porosity and thickness of the porous metal plate may depend on the efficiency with which the particles may be collected and the fluid/gas conductance.

The pressure range for the fluid in the conduit can be in the range of 10⁻¹ to 10⁻² torr, although other ranges are also within the scope of this embodiment. The frequency range of the RF source can be in the range of 10-40 MHz, for example, although other ranges are also within the scope of this embodiment. The power used to power the RF source and generate plasma can be in the range of 10²-10³ Watts, although other ranges are also within the scope of this embodiment. In some embodiments, the diameter of the particles can be an average of about 10 nm. The concentration of the particles can be around 10⁻³ particles per cubic centimeter. The flow rate of the fluid can be around 5000 standard cubic centimeters per minute (sccm). The detection limit of the electrometer can be around 0.1 fA or higher. The fluid within the processing system may include any gas such as nitrogen or any inert gas including but not limited to argon, neon, helium, krypton, xenon, and radon.

The preceding description sets forth numerous specific details such as examples of specific systems, components, methods, and so forth, in order to provide a good understanding of several embodiments of the present invention. It will be apparent to one skilled in the art, however, that at least some embodiments of the present invention may be practiced without these specific details. In other instances, well-known components or methods are not described in detail or are presented in simple block diagram format in order to avoid unnecessarily obscuring the present invention. Thus, the specific details set forth are merely exemplary. Particular implementations may vary from these exemplary details and still be contemplated to be within the scope of the present invention.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±10%.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

It is to be understood that the above description is intended to be illustrative, and not restrictive. Many other embodiments will be apparent to those of skill in the art upon reading and understanding the above description. The scope of the invention should, therefore, be determined with reference to the appended claims, along with the full scope of equivalents to which such claims are entitled.

What is claimed is:

1. A processing system, comprising:
a processing chamber defining a processing region;
a foreline coupled with the processing chamber, the foreline defining a fluid conduit;
a plasma trap provided within an interior of the foreline, the plasma trap configured to charge and trap at least some particles in the fluid conduit; and
a particle detector to measure a quantity of particles trapped in the plasma trap.

2. The processing system of claim 1, wherein the plasma trap further comprises:
a first ring electrode installed within the interior of the foreline;
a second ring electrode installed at a predetermined distance from the first ring electrode; and
a radio frequency (RF) source coupled to the first ring electrode and the second ring electrode, the radio frequency source configured to apply an RF signal to the first ring electrode and the second ring electrode to generate a plasma in a region between the first ring electrode and the second ring electrode, wherein the plasma is to charge and trap the at least some particles in the fluid conduit.

3. The processing system of claim 1, further comprising:
a first insulating material between the first ring electrode and an inner annulus of the foreline; and
a second insulating material between the second ring electrode and the inner annulus of the foreline.

4. The processing system of claim 2, wherein the particle detector comprises:
a metal plate for collecting at least some of the at least some particles; and
an electrometer operatively coupled to the metal plate, the electrometer configured to measure an electric current based on the at least some particles collected on the metal plate over a predetermined period of time.

5. The processing system of claim 4, further comprising:
a grounded metal mesh installed downstream from the second ring electrode, the grounded metal mesh configured to block ions and electrons from passing onto the metal plate.

6. The processing system of claim 4, wherein the predetermined period of time is based at least in part on a diameter of a smallest particle in the particles, a concentration of the particles in the fluid, a flow rate of the fluid, or the least current measurable by the electrometer.

7. The processing system of claim 4, wherein the metal plate comprises at least one of nickel, copper, gold, silver, platinum, stainless steel, or other conductive materials.

8. The processing system of claim 1, further comprising:
an outlet pump coupled to a distal end of the fluid conduit, the outlet pump configured to expunge the fluid out of the foreline.

9. The processing system of claim 1, further comprising:
a metal coil wound around an outside surface of the foreline comprising an electrically insulating material; and
an RF source coupled to the metal coil for generating plasma within the foreline.

10. A method, comprising:
electrostatically charging, through a plasma source, particles in a medium, to form charged particles;
trapping the charged particles in a chamber for a time period;
turning off the plasma source to release the charged particles to flow into a conduit;
collecting at least some of the charged particles released in the conduit onto a conductive medium; and
measuring an electric current produced by the charged particles collected on the conductive medium.

11. The method of claim 10, further comprising:
trapping the charged particles for a first period of time in the chamber; and
releasing, at termination of the first period of time, the charged particles into the conduit.

12. The method of claim 10, wherein a diameter of the charged particles is less than or larger than 100 nm.

13. The method of claim 10, wherein a particle concentration of the charged particles is less than 400 particles/cm³.

14. A method, comprising:
providing a plasma trap in a conduit of a processing chamber;
charging particles in the plasma trap for a predetermined period of time;
releasing the charged particles after the predetermined period of time;
collecting at least some of the charged particles on a metal plate; and
measuring an electric current produced by the charged particles collected on the metal plate.

15. The method of claim 14, further comprising:
generating plasma in the plasma trap using at least one of a capacitive coupling (CCP) mode or an inductive coupling (ICP) mode of the plasma trap.

16. The method of claim 14, wherein the metal plate covers at least 50% of an area within the conduit.

17. The method of claim 14, further comprising:
activating an outlet pump at termination of the predetermined period of time to release the charged particles onto the metal plate.

18. The method of claim 14, wherein the metal plate comprises at least one of nickel, copper, gold, silver, platinum, stainless steel, or other conductive materials.

19. The method of claim 14, further comprising:
separating, using a metal mesh, ions and electrons in the plasma from passing to the metal plate.

20. The method of claim 14, wherein a diameter of the charged particles is less than 100 nm or a particle concentration of the charged particles is less than 400 particles/cm³.
